(19) United States
(12) Patent Application Publication
(10) Pub. No.: US 2006/0166458 A1
(43) Pub. Date: Jul. 27, 2006

(54) Method for forming shallow trench isolation structures

(76) Inventors: Yi-Lung Cheng, Danshuei Township (TW); Szu-An Wu, Hsin-Chu (TW); Yi-Lang Wang, Tien-Chung Village (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 11/044,814

(22) Filed: Jan. 26, 2005

(51) Int. Cl. H01L 21/76; H01L 21/461

(52) U.S. Cl. 438/424; 438/438; 438/692

(57) ABSTRACT

A shallow trench isolation (STI) structure for semiconductor devices is formed using a deposited silicon layer formed over a polish stop layer formed over an oxide formed on a substrate. The polish stop layer may be nitride. An opening is formed extending through the deposited silicon layer and the nitride and oxide layers and extending into the substrate. A deposited oxide is formed filling the opening and extending over the top surface of deposited silicon layer. A chemical mechanical polishing operation polishes the deposited silicon layer at a rate faster than the deposited oxide layer to produce an STI with a convex portion extending above the nitride layer. Dishing problems are avoided and the structure may be subsequently planarized.

### FIELD OF THE INVENTION

The present invention relates to a method of isolation for integrated circuits (IC), and more specifically to a method for forming shallow trench isolation structures using a silicon polishing film.

### BACKGROUND

The advent of ultra large scale integrated (ULSI) circuits have allowed semiconductor manufacturers worldwide to fabricate semiconductor devices to extremely compact dimensions. The fabrication process for forming semiconductor devices includes the formation of isolation structures within the semiconductor device. In order to fabricate a highly integrated circuit, isolation structures are formed in the substrate to isolate, i.e. insulate, the various devices of the integrated circuit from one another. In the fabrication of a ULSI circuit, even a small amount of leakage in the device can induce significant power dissipation for the overall circuit so effective isolation devices are a requirement.

Trench isolation structures are insulating structures primarily used for electrically isolating devices in ULSI and VLSI (very large scale integrated) circuits and hence may be considered a replacement for conventional LOCOS (LOCal Oxidation of Silicon) isolation. In basic shallow trench isolation (STI) technology, shallow trenches are anisotropically etched into the substrate which is formed of silicon. A CVD oxide may then be deposited onto the substrate and filing the shallow trenches. The CVD oxide is then planarized using chemical mechanical polishing (CMP) or other etch back techniques. The CMP process typically uses a pad oxide formed over the substrate and a silicon nitride that serves as a polishing-stop layer, formed over the pad oxide.

Problems associated with the formation of shallow trench isolation devices using chemical mechanical polishing, include erosion of the nitride and a dishing effect whereby the CVD oxide being polished takes on a depressed concave shape and is recessed below the polishing-stop nitride surface because the CVD oxide polishes at a rate faster than the nitride. After the nitride film is removed, this dishing phenomenon degrades the planarity of the structures and creates problems in the subsequent films formed over the structure. The dishing effect also impacts the control of implantation during various implantation processes.

It would therefore be desirable to produce a shallow trench isolation structure that is resistant to the aforementioned shortcomings and easy to manufacture.

### SUMMARY OF THE INVENTION

To address these and other needs and in view of its purposes, a method is provided for forming an isolation structure in a semiconductor device. The method includes forming a polishing resistant layer over a substrate, forming a buffer layer over the polishing resistant layer, forming a trench with smooth sidewalls by etching through the buffer layer and the polishing resistant layer and into the substrate, the smooth sidewalls formed of portions of the substrate, the polishing resistant layer and the buffer layer. The method further provides forming an insulating layer over the buffer layer and filling the trench, and polishing to remove the insulating layer from over the polishing resistant layer using a polishing operation that removes the buffer layer at a rate faster than the deposited insulator.

Another method provides for forming an oxide layer over a substrate, forming a polish stop layer over the oxide layer, depositing a silicon layer over the polish stop layer, defining a trench region, forming a trench with straight sidewalls by etching through the silicon layer, the polish stop layer, the oxide layer, and into the substrate in the trench region, the straight sidewalls formed of portions of the substrate, the oxide layer, the polish stop layer and the silicon layer, then depositing a deposited oxide layer over the silicon layer and filling the trench, and polishing to remove the deposited oxide layer from over the polish stop layer.

Another exemplary method for forming an isolation structure in a semiconductor device provides forming a polishing resistant layer over a substrate, depositing a buffer layer over the polishing resistant layer, defining a trench region, forming a trench with straight sidewalls by etching through the buffer layer and the polishing resistant layer, and into the substrate in the trench region, the straight sidewalls formed of portions of the substrate, the polishing resistant layer and the buffer layer. The method further provides depositing a deposited oxide layer over the buffer layer and filling the trench; and polishing to remove the deposited oxide layer from over the polishing resistant layer using a polishing operation that produces a structure in which portions of the deposited oxide layer extend above a top surface of the polishing resistant layer in the trench region.

### BRIEF DESCRIPTION OF THE DRAWING

The present invention is best understood from the following detailed description when read in conjunction of the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1-5 illustrate sequence of processing operations used to form an exemplary STI according to the invention:

FIG. 1 shows films including a deposited silicon film, formed over a substrate;

FIG. 2 shows a trench opening formed in the structure shown in FIG. 1;

FIG. 3 shows a deposited oxide formed over and in the structure shown in FIG. 2;

FIG. 4 shows an exemplary STI formed by polishing; and

FIG. 5 shows the structure of FIG. 4 after it has been planarized.

### DETAILED DESCRIPTION

FIG. 1 is a cross-sectional view that shows a plurality of films formed over a substrate. Substrate 1 may be a silicon substrate or a substrate formed of other semiconductor material, and which may be used to form semiconductor devices such as integrated circuits in various technologies such as ULSI and VLSI technologies. First dielectric 3 is formed over surface 1 and may be a thermally formed pad oxide, a deposited oxide, or other suitable dielectric. Polishing resistant layer 5 is formed over first dielectric 3 and may be formed using conventional methods. First dielectric 3 may be a pad oxide that advantageously relieves the stress associated with the formation of polishing resistant layer 5. In one exemplary embodiment, polishing resistant polishing resistant layer 5 may be silicon nitride or another nitride and may be referred to as a polish stop layer. Buffer layer 7 is formed over polishing resistant layer 5 and may be formed using suitable conventional deposition methods. In one exemplary embodiment, buffer layer 7 may be a deposited silicon layer which may be polysilicon or amorphous silicon. The deposited silicon layer may be a doped silicon material. Buffer layer 7 may include thickness 8 of 200 to 600 angstroms in one exemplary embodiment, but other thicknesses may be used in other exemplary embodiments. Buffer layer 7 is chosen to have a higher removal rate than the deposited insulator later used to fill a subsequently formed trench, in the polishing operation used to remove the deposited insulator from over the substrate and form the STI structure. This is shown in subsequent figures.

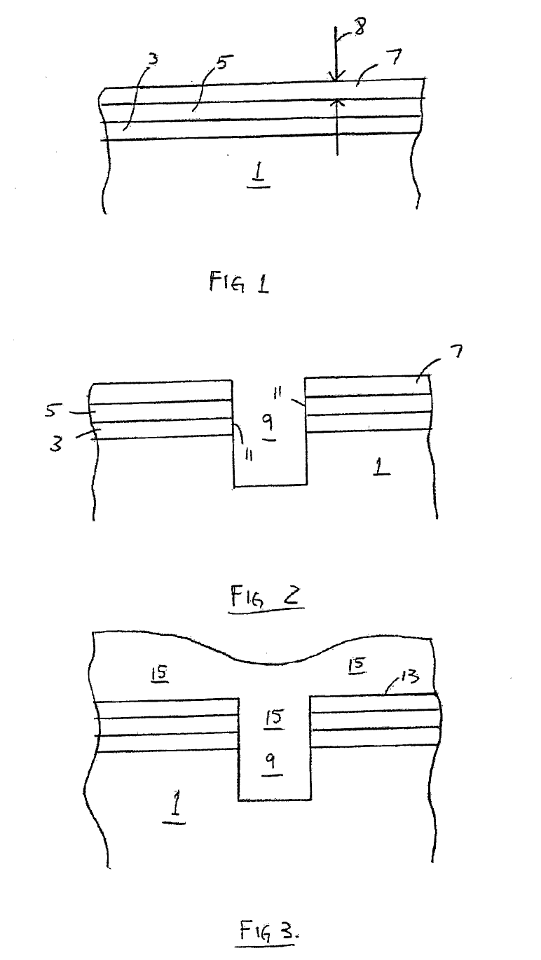

Patterning and etching processes are then used to form opening 9 shown in FIG. 2. Conventional photoresist materials and patterning techniques may be used to form a pattern in a masking film and a plasma etch process such as reactive ion etching may be used to form opening 9 that extends through buffer layer 7, polishing resistant layer 5, first dielectric 3 and into substrate 1. The characteristics of the etch process or processes are controlled to produce an anisotropic etch. In one exemplary embodiment, an in-situ, substantially continuous anisotropic etch process sequence may be used to form opening 9 by etching through the successive layers. Straight sidewalls 11 include portions of substrate 1, first dielectric 3, polishing resistant layer 5 and buffer layer 7. Straight sidewalls 11 are also seen to be smooth and free of irregularities, recesses or indentations. Opening 9 will be used to form an STI and is advantageously formed at a location of substrate 1 where it will isolate various active devices from one another. During the formation process, a plurality of openings 9 may be formed throughout substrate 1 to accommodate the subsequent formation of STI devices. The depth that opening 9 extends into substrate 1 may vary depending on application.

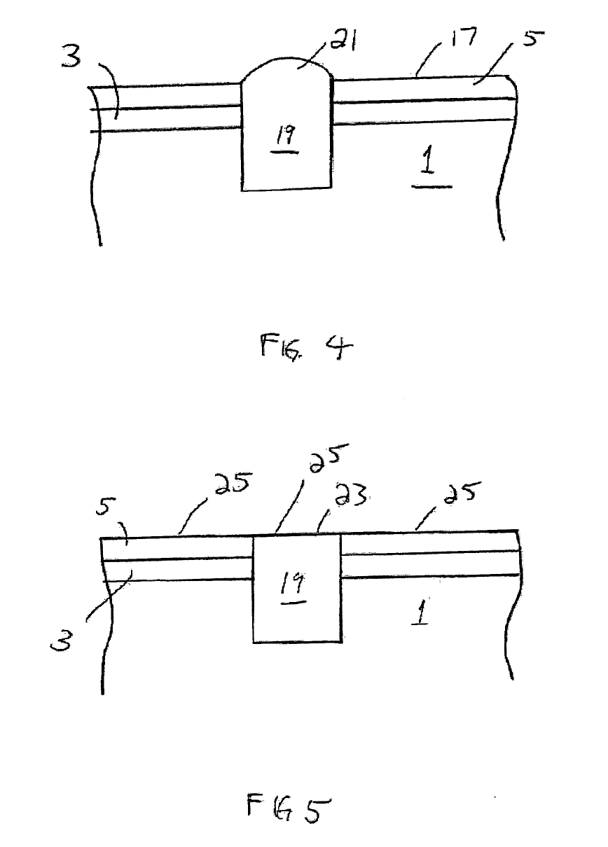

FIG. 3 shows the structure of FIG. 2 after deposited insulator 15 has been formed over top surface 13 of buffer layer 7. In one embodiment, deposited insulator 15 may advantageously be an oxide. Deposited insulator 15 also fills opening 9. Chemical vapor deposition may be used to form deposited insulator 15. In one exemplary embodiment, chemical vapor deposition (CVD) using a high density plasma (HDP) may be used. Other deposition methods may be used in other exemplary embodiments. In one exemplary embodiment, deposited insulator 15 may be TEOS, tetraethylorthosilicate, but other deposited oxides or other insulating materials may be used in other exemplary embodiments.

The structure of FIG. 3 is then polished using a CMP operation. Conventional systems may be used. The polishing conditions are chosen so that the buffer layer is removed by polishing at a removal rate faster than the deposited insulator material. In an exemplary embodiment in which the deposited insulator 15 is an oxide, the buffer layer is deposited silicon and the polishing resistant layer is a nitride, the relative removal rates for deposited silicon:deposited oxide:nitride may be 100:4:1. In one embodiment the removal rate of the deposited silicon is at least 20 times greater than the polishing rate of the deposited oxide. Conventional CMP operations may be used with suitable and commercially available chemicals to produce the desired removal rates and relative removal rates. In one exemplary embodiment, the CMP operation may include silica, Al₂O₃, KOH and/or NH₄OH as chemical components. It is because the buffer layer has a faster removal rate than the deposited oxide or other insulator in the polishing operation employed, that dishing is avoided. Dishing occurs when the trench fill material such as a deposited oxide, is formed over a polishing stop layer and is removed at a faster rate than the polishing stop layer and unevenly recedes below the surface of the polishing stop layer and takes on depressed concave shape when the polishing operation terminated upon exposure of the polishing stop layer.

According to the polishing operation of the invention, however, once buffer layer 7 is exposed during the polishing operation, the material removal rate is greater for buffer layer 7 than for the deposited insulator 15. The polishing operation continues until top surface 17 of polishing resistant layer 5 is exposed, and produces the structure shown in FIG. 4 in which section 21 of STI 19 extends above top surface 17 of polishing resistant layer 5. Polishing resistant layer 5 is not appreciably receded during the polishing operation and serves as the polishing stop layer. After the structure shown in FIG. 4 is formed, a global polishing operation may be used to planarize the structure and produce the planarized structure shown in FIG. 5. FIG. 5 shows STI 19 extending within substrate 1 and STI 19 includes substantially planar STI surface 23 which is co-planar with surrounding surfaces and forms planar top surface 25. Dishing is avoided.

The structure shown in FIG. 5 may then be further processed using conventional technologies to remove polishing resistant layer 5. Conventional selective wet etching processes may be used. STI 19 may be formed and used at various locations within various integrated circuit devices that may be formed in substrate 1, to electrically isolate active device features from one another. Semiconductor devices may then be formed in or on substrate 1 such that various features of the devices are isolated, i.e., insulated from one another by STI's such as STI 19.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,”, “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming an isolation structure in a semiconductor device, said method comprising:
forming a polishing resistant layer over a substrate;
forming a buffer layer over said polishing resistant layer;
forming a trench with smooth sidewalls by etching through said buffer layer and said polishing resistant layer and into said substrate, said smooth sidewalls formed of portions of said substrate, said polishing resistant layer and said buffer layer;
forming an insulating layer over said buffer layer and filling said trench; and
polishing to remove said insulating layer from over said polishing resistant layer using a polishing operation that removes said buffer layer at a rate faster than said insulating layer.

2. The method as in claim 1, wherein said polishing resistant layer is a silicon nitride layer.

3. The method as in claim 2, wherein said buffer layer is formed directly on said silicon nitride layer and said silicon nitride layer is formed directly on a dielectric layer formed directly on said substrate.

4. The method as in claim 1, further comprising thermally oxidizing said substrate to form a pad oxide on said substrate and wherein said forming a polishing resistant layer over a substrate comprises forming a nitride on said pad oxide and said forming a trench further comprises etching through said pad oxide.

5. The method as in claim 1 wherein said polishing further removes said buffer layer from over said polishing resistant layer.

6. The method as in claim 1, wherein said buffer layer comprises a silicon layer, a polysilicon layer or an amorphous silicon layer.

7. The method as in claim 6, wherein said chemical mechanical polishing includes at least one of silica, Al₂O₃, KOH and NH₄OH.

8. The method as in claim 6, wherein said insulating layer has a first polishing rate and said buffer layer has a second polishing rate that is at least 20 times faster than said first polishing rate.

9. The method as in claim 8, wherein said polishing resistant layer has a third polishing rate, and a ratio of said first polishing rate to said second polishing rate to said third polishing rate is about 100:4:1.

10. The method as in claim 1, wherein said polishing produces a structure in which portions of said insulating layer extend above a top surface of said polishing resistant layer over said trench.

11. The method as in claim 10, further comprising planarizing after said polishing and removing said polishing resistant layer after said planarizing.

12. The method as in claim 1, wherein said polishing comprises chemical mechanical polishing.

13. The method as in claim 1, wherein said insulating layer comprises TEOS or an HDP oxide.

14. A method for forming an isolation structure in a semiconductor device, said method comprising:
forming an oxide layer over a substrate;
forming a polish stop layer over said oxide layer;
depositing a silicon layer over said polish stop layer;
defining a trench region;
forming a trench with straight sidewalls by etching through said silicon layer, said polish stop layer, said oxide layer, and into said substrate in said trench region, said straight sidewalls formed of portions of said substrate, said oxide layer, said polish stop layer and said silicon layer;
depositing a deposited oxide layer over said silicon layer and filling said trench; and
polishing to remove said deposited oxide layer from over said polish stop layer.

15. The method as in claim 14, wherein said polishing comprises chemical mechanical polishing that further removes said silicon layer from over said polish stop layer, at a rate faster than said deposited oxide layer.

16. The method as in claim 14, wherein said polish stop layer comprises a nitride.

17. The method as in claim 14, wherein said polishing produces a structure in which portions of said deposited oxide layer extend above a top surface of said polish stop layer in said trench region.

18. A method for forming an isolation structure in a semiconductor device, said method comprising:
forming a polishing resistant layer over a substrate;
depositing a buffer layer over said polishing resistant layer;
defining a trench region;
forming a trench with straight sidewalls by etching through said buffer layer and said polishing resistant layer, and into said substrate in said trench region, said straight sidewalls formed of portions of said substrate, said polishing resistant layer and said buffer layer;
depositing a deposited oxide layer over said buffer layer and filling said trench; and
polishing to remove said deposited oxide layer from over said polishing resistant layer using a polishing operation that produces a structure in which portions of said deposited oxide layer extend above a top surface of said polishing resistant layer in said trench region.

19. The method as in claim 18, wherein said polishing resistant layer comprises silicon nitride and said buffer layer comprises silicon.

20. The method as in claim 19, wherein said polishing comprises chemical mechanical polishing that further removes said silicon layer at a rate faster than said deposited oxide layer.
